(19) United States
(12) Patent Application Publication
(10) Pub. No.: US 2025/0105193 A1
(43) Pub. Date: Mar. 27, 2025

(54) SEMICONDUCTOR PACKAGE

(71) Applicant: SAMSUNG ELECTRONICS CO., LTD., Suwon-si (KR)

(72) Inventors: Jungmin Ko, Suwon-si (KR); Hyunhee Lee, Suwon-si (KR); Hojun Lee, Suwon-si (KR); Dongjoo Choi, Suwon-si (KR)

(73) Assignee: SAMSUNG ELECTRONICS CO., LTD., Suwon-si (KR)

(21) Appl. No.: 18/890,118

(22) Filed: Sep. 19, 2024

(30) Foreign Application Priority Data
Sep. 22, 2023 (KR) 10-2023-0127369
Feb. 1, 2024 (KR) 10-2024-0016220

(51) Int. Cl. H01L 23/00; H01L 23/498; H01L 25/065; H10B 80/00

(52) U.S. Cl. CPC H01L 24/16; H01L 24/05; H01L 24/09; H01L 24/13; H01L 24/17; H01L 25/0657; H01L 23/498; H01L 24/32; H01L 24/33; H01L 24/73; H01L 2224/0401; H01L 2224/05624; H01L 2224/05655; H01L 2224/09181; H01L 2224/13083; H01L 2224/13111; H01L 2224/13139; H01L 2224/13144; H01L 2224/13147; H01L 2224/16146; H01L 2224/16503; H01L 2224/17181; H01L 2224/32145; H01L 2224/33181; H01L 2224/73204; H01L 2225/06541; H10B 80/00

(57) ABSTRACT

A semiconductor package includes a first semiconductor chip including a first through-via and a first upper pad, a second semiconductor chip provided on the first semiconductor chip and including a second lower pad, and a bonding bump provided between the first semiconductor chip and the second semiconductor chip and connected to the first upper pad and the second lower pad. The bonding bump includes: a conductive pattern directly contacting the second lower pad and including nickel and a bonding structure directly contacting the conductive pattern and the first upper pad, wherein the bonding structure includes an intermetallic compound including copper and a solder material. A thickness of the bonding structure is from about 47% to about 54% of a sum of a thickness of the conductive pattern, a thickness of the bonding structure, and a thickness of the first upper pad.

### CROSS-REFERENCE TO RELATED APPLICATIONS

This application claims priority to Korean Patent Application Nos. 10-2023-0127369, filed on Sep. 22, 2023 and 10-2024-0016220, filed on Feb. 1, 2024, in the Korean Intellectual Property Office, the disclosures of which are incorporated by reference herein in their entireties.

### BACKGROUND

The present disclosure relates to a semiconductor package, and more particularly, to a semiconductor package including bumps.

Semiconductor packages include an integrated circuit (IC) chip implemented in a form suitable for use in electronic products. Semiconductor packages may include a semiconductor chip mounted on a printed circuit board. Semiconductor chips may have electrical connection terminals, such as solder balls or bumps to be electrically connected to other electronic semiconductor chips or to printed circuit boards. Demand for improved electrical connection characteristics between semiconductor chips and miniaturization of semiconductor packages has increased.

### SUMMARY

One or more example embodiments provide semiconductor packages with improved long-term reliability and durability.

According to an aspect of one or more example embodiments, a semiconductor package includes: a first semiconductor chip including a first through-via and a first upper pad; a second semiconductor chip provided on the first semiconductor chip and including a second lower pad; and a bonding bump provided between the first semiconductor chip and the second semiconductor chip and connected to the first upper pad and the second lower pad, wherein the bonding bump includes: a conductive pattern directly contacting the second lower pad and including nickel; and a bonding structure directly contacting the conductive pattern and the first upper pad, wherein the bonding structure includes an intermetallic compound including copper and a solder material, and wherein a thickness of the bonding structure is from about 47% to about 54% of a sum of a thickness of the conductive pattern, a thickness of the bonding structure, and a thickness of the first upper pad.

According to a further aspect of one or more example embodiments, a semiconductor package includes: a semiconductor chip including: a lower pad; a through-electrode; and an upper pad, wherein the upper pad is disposed on an upper surface of the semiconductor chip and is connected to the through-electrode; and a bump provided on a lower surface of the semiconductor chip, wherein the bump includes: a conductive pattern directly contacting a lower surface of the lower pad and including nickel; a solder ball provided on a lower surface of the conductive pattern; and a metal pattern directly contacting the lower surface of the conductive pattern and an upper surface of the solder ball and including copper, wherein a maximum thickness of the solder ball is from about 50% to about 61% of a sum of a thickness of the conductive pattern, a thickness of the metal pattern, a maximum thickness of the solder ball, and a thickness of the upper pad, and wherein the thickness of the metal pattern is from about 7% to about 9% of the sum of the thickness of the conductive pattern, the thickness of the metal pattern, the maximum thickness of the solder ball, and the thickness of the upper pad.

According to a still further aspect of one or more example embodiments, a semiconductor package includes: a lower semiconductor chip including a conductive pad on an upper surface of the lower semiconductor chip; lower bumps provided on a lower surface of the lower semiconductor chip; a first semiconductor chip disposed on the upper surface of the lower semiconductor chip and including a first lower pad, a first through-via, and a first upper pad; a first bonding bump provided between the lower semiconductor chip and the first semiconductor chip and connected to the conductive pad and the first lower pad; a first insulating film provided between the lower semiconductor chip and the first semiconductor chip and covering a sidewall of the first bonding bump; a second semiconductor chip disposed on an upper surface of the first semiconductor chip and including a second lower pad; a second bonding bump provided between the first semiconductor chip and the second semiconductor chip and connected to the first upper pad and the second lower pad; a second insulating film provided between the first semiconductor chip and the second semiconductor chip and covering a sidewall of the first bonding bump; and a molding film disposed on the upper surface of the lower semiconductor chip and covering a sidewall of the first semiconductor chip and a sidewall of the second semiconductor chip, wherein the first bonding bump includes: a first conductive pattern directly contacting the lower surface of the first lower pad and including nickel; and a first bonding structure directly contacting the first conductive pattern and the conductive pad, wherein the first bonding structure includes a first intermetallic compound including copper and a solder material, wherein the second bonding bump includes: a second conductive pattern contacting a lower surface of the second lower pad and including nickel; and a second bonding structure directly contacting the second conductive pattern and the first upper pad, wherein the second bonding structure includes a second intermetallic compound including copper and a solder material, wherein a thickness of the first bonding structure is from about 47% to about 54% of a gap between the lower semiconductor chip and the first semiconductor chip, and wherein a thickness of the second bonding structure is from about 47% to about 54% of a gap between the first semiconductor chip and the second semiconductor chip.

### BRIEF DESCRIPTION OF THE DRAWINGS

The above and other aspects and features will be more apparent from the following detailed description of one or more example embodiments taken in conjunction with the accompanying drawings, in which:

FIG. 1A is a cross-sectional view illustrating a semiconductor device according to one or more example embodiments;

FIG. 1B is an enlarged view of region I of FIG. 1A, according to one or more example embodiments;

FIG. 2A is a cross-sectional view illustrating a semiconductor package according to one or more example embodiments;

FIG. 2B is an enlarged view of region II of FIG. 2A, according to one or more example embodiments;

FIGS. 2C and 2D are diagrams illustrating a bonding process between a first semiconductor chip and a second semiconductor chip according to one or more example embodiments;

FIG. 2E is an enlarged view of region III of FIG. 2A, according to one or more example embodiments;

FIG. 2F is an enlarged view of region IV of FIG. 2A, according to one or more example embodiments;

FIG. 2G is an enlarged view of region V of FIG. 2A, according to one or more example embodiments;

FIG. 3 is a diagram illustrating a second bonding structure according to one or more example embodiments;

FIG. 4 is a diagram illustrating a semiconductor package according to one or more example embodiments;

FIG. 5A is a diagram illustrating a semiconductor package according to one or more example embodiments; and

FIG. 5B is a diagram illustrating a semiconductor package according to one or more example embodiments.

### DETAILED DESCRIPTION

Hereinafter, one or more example embodiments will be described in detail with reference to the accompanying drawings. The same reference numerals may refer to the same elements throughout and duplicate descriptions thereof are omitted. Hereinafter, a semiconductor device and a semiconductor package according to one or more example embodiments are described.

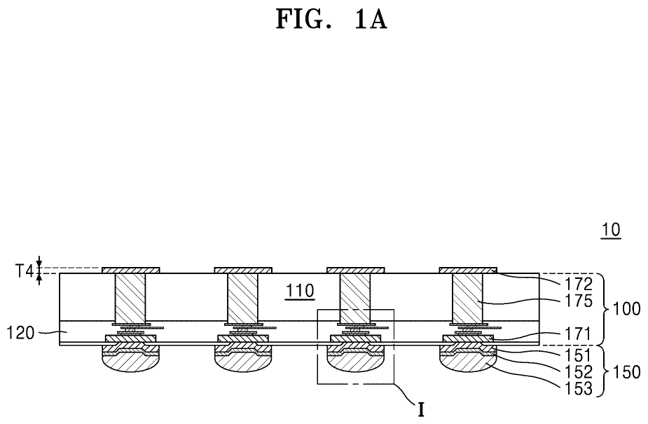

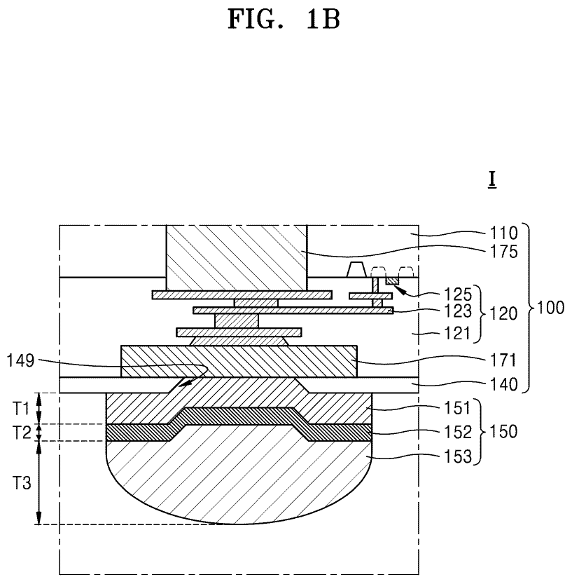

FIG. 1A is a cross-sectional view illustrating a semiconductor device 10 according to one or more example embodiments. FIG. 1B is an enlarged view of region I of FIG. 1A, according to one or more example embodiments.

Referring to FIGS. 1A and 1B, the semiconductor device 10 may include a semiconductor chip 100 and bumps 150. For example, the semiconductor chip 100 may be a memory chip, such as a high bandwidth memory (HBM) chip. According to one or more example embodiments, the memory chip may be a logic chip or a buffer chip.

The semiconductor chip 100 may include a semiconductor substrate 110, a circuit layer 120, lower pads 171, through-vias 175, and upper pads 172. The semiconductor substrate 110 may include, for example, a semiconductor material, such as silicon, germanium, or silicon-germanium.

The circuit layer 120 may be provided on a lower surface of the semiconductor substrate 110. The circuit layer 120 may include an integrated circuit (IC) 125, an insulating layer 121, and interconnections 123, as shown in FIG. 1B. The IC 125 may be provided on the lower surface of the semiconductor substrate 110. The IC 125 may include, for example, transistors. The insulating layer 121 may be provided on the lower surface of the semiconductor substrate 110 and may cover the IC 125. The insulating layer 121 may include a plurality of layers. The insulating layer 121 may include a silicon-containing insulating material. The silicon-containing insulating material may include, for example, silicon oxide, silicon nitride, silicon oxynitride, and/or tetraethyl orthosilicate. The interconnections 123 may be provided within the insulating layer 121. The interconnections 123 may be electrically connected to the IC 125. According to one or more example embodiments, being electrically connected to a semiconductor chip may refer to being electrically connected to an IC of the semiconductor chip. Being electrically connected may include a direct connection or an indirect connection through another conductive component.

As shown in FIG. 1A, the upper pads 172 may be provided on an upper surface of the semiconductor chip 100. The upper surface of the semiconductor chip 100 may include an upper surface of the semiconductor substrate 110 but is not limited thereto. The upper pads 172 may be laterally apart from each other. The fact that any two components are laterally apart from each other may mean that they are apart from each other horizontally. “Being horizontal” may refer to being parallel to the upper surface of the semiconductor substrate 110.

The through-vias 175 are provided within the semiconductor chip 100 and may be electrically connected to the upper pads 172, respectively. For example, the through-vias 175 may penetrate the upper and lower surfaces of the semiconductor substrate 110. The through-vias 175 may further pass through an upper portion of the circuit layer 120. The through-vias 175 may include metal materials, such as tungsten, titanium, copper, and/or aluminum.

The lower pads 171 may be provided on a lower surface of the semiconductor chip 100. The lower pads 171 may be laterally apart from each other. The lower pads 171 may be electrically connected to the through-vias 175. Accordingly, the lower pads 171 may be electrically connected to the upper pads 172 through the through-vias 175. As shown in FIG. 1B, the lower pads 171 may be electrically connected to the IC 125 through the interconnections 123 within the circuit layer 120. The lower pads 171 may include a first conductive material. The first conductive material may include, for example, aluminum or an aluminum alloy.

The semiconductor chip 100 may further include a protective layer 140. The protective layer 140 may be provided on a lower surface of the circuit layer 120. The protective layer 140 may cover lower surfaces of edge regions of the lower pads 171. The protective layer 140 may have a pad opening 149. The pad opening 149 may pass through upper and lower surfaces of the protective layer 140 and may expose lower surfaces of center regions of the lower pads 171. According to one or more example embodiments, the protective layer 140 may include an insulating material that is different from that of the insulating layer 121. The protective layer 140 may include an insulating organic material, such as photosensitive polyimide (PSPI). According to one or more example embodiments, the protective layer 140 may include a silicon-based insulating material, such as silicon nitride.

The bumps 150 may be provided on a lower surface of the semiconductor chip 100. For example, the bumps 150 may be provided on lower surfaces of the lower pads 171 and may be electrically connected to the lower pads 171. According to one or more example embodiments, for simplicity of description, a single lower pad 171 is described, but one or more example embodiments are not limited thereto.

Each of the bumps 150 may include a conductive pattern 151, a metal pattern 152, and a solder ball 153. The conductive pattern 151 may be provided in the pad opening 149 to cover a lower surface of the center region of the lower pad 171. For example, the conductive pattern 151 may directly contact the lower pad 171. According to one or more example embodiments, no other components may be located between the conductive pattern 151 and the lower pad 171. The conductive pattern 151 may extend onto a lower surface of the protective layer 140 and may cover the lower surface of the protective layer 140. The conductive pattern 151 may include a first metal. The first metal may include, for example, nickel and/or a nickel alloy. The conductive pattern 151 may function as a barrier film but one or more example embodiments are not limited thereto.

A solder ball 153 may be provided on a lower surface of the conductive pattern 151. The solder ball 153 may include a metal different from the conductive pattern 151. The solder ball 153 may include a solder material. The solder material may include tin (Sn), silver (Ag), and/or alloys thereof.

The metal pattern 152 may be provided between the conductive pattern 151 and the solder ball 153. The metal pattern 152 may directly contact the conductive pattern 151 and the solder ball 153. A width of the metal pattern 152 may be substantially equal to a width of the conductive pattern 151. The metal pattern 152 may include a second metal. The second metal may include a metal that is different from the first metal and solder material. For example, the second metal may include copper and/or a copper alloy.

According to one or more example embodiments, a maximum thickness (T3 in FIG. 1B) of the solder ball 153 may be about 50% to about 61% of the sum of a thickness T1 of the conductive pattern 151, a thickness T2 of the metal pattern 152, the maximum thickness T3 of the solder ball 153, and a thickness T4 of the upper pads 172 of FIG. 1A. The thickness (T2 in FIG. 1B) of the metal pattern 152 may be about 7% to about 9% of the sum of the thickness T1 of the conductive pattern 151, the thickness T2 of the metal pattern 152, the maximum thickness T3 of the solder ball 153, and the thickness T4 of the upper pads 172. The thickness (T1 in FIG. 1B) of the conductive pattern 151 may be about 20% to about 25% of the sum of the thickness T1 of the conductive pattern 151, the thickness T2 of the metal pattern 152, the maximum thickness T3 of the solder ball 153, and the thickness T4 of the upper pads 172. The thickness T4 of the upper pads 172 in FIG. 1A may be about 19% to about 24% of the sum of the thickness T1 of the conductive pattern 151 in FIG. 1B, the thickness T2 of the metal pattern 152, and the maximum thickness T3 of the solder ball 153, and the thickness T4 of the upper pads 172.

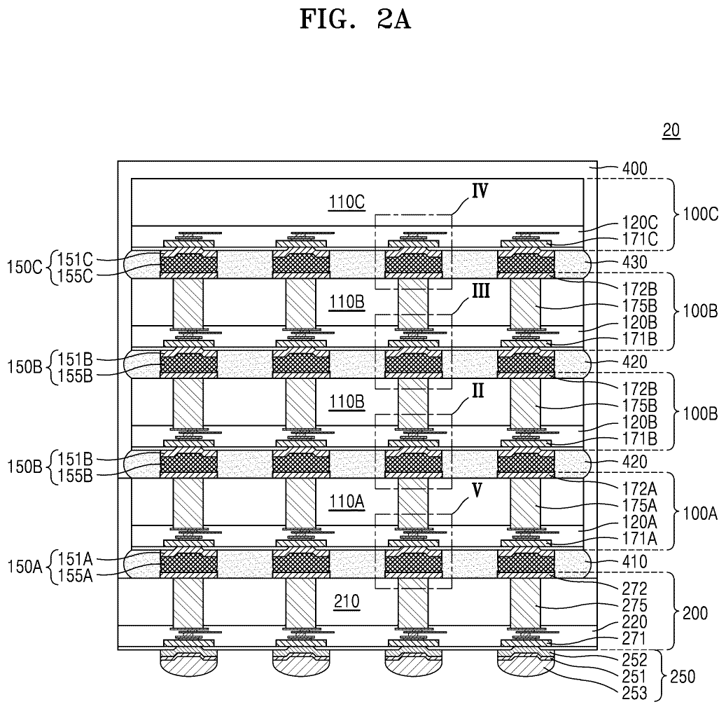

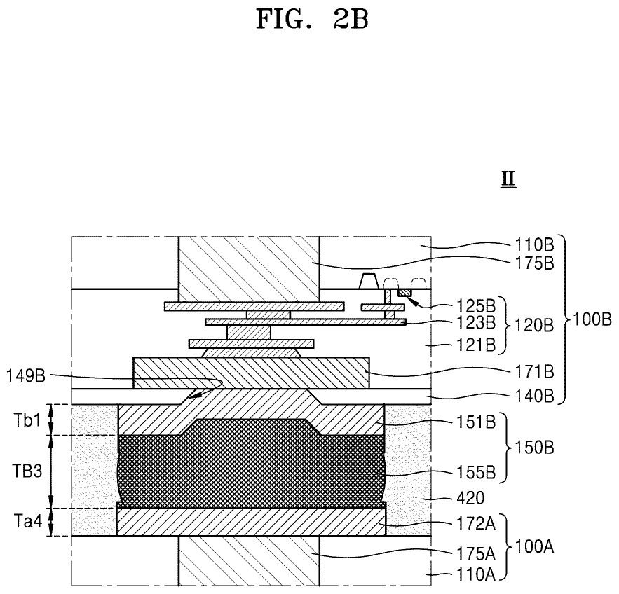

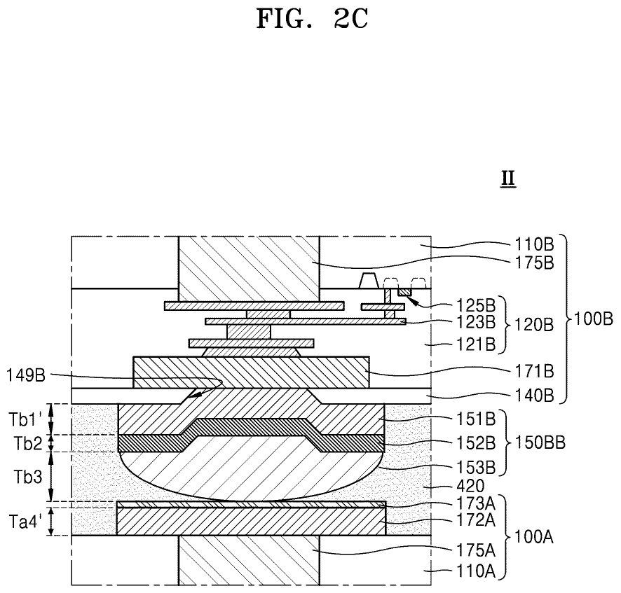

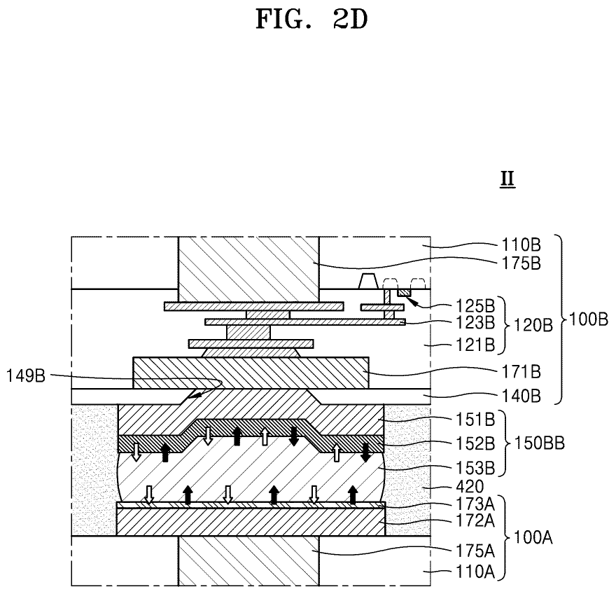

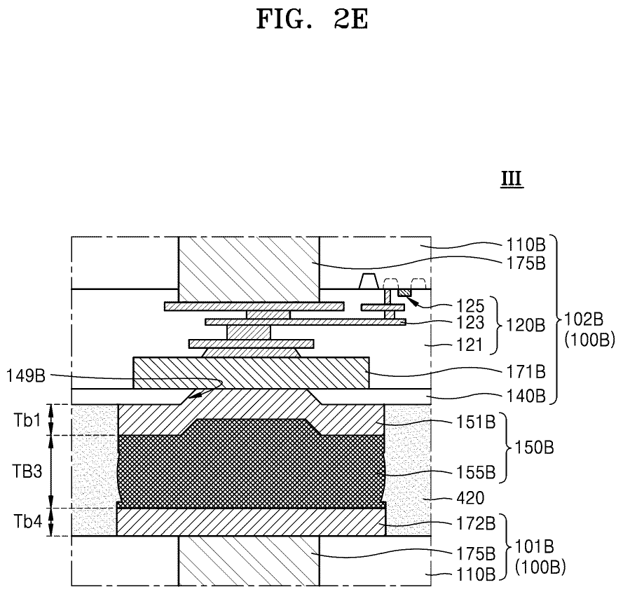

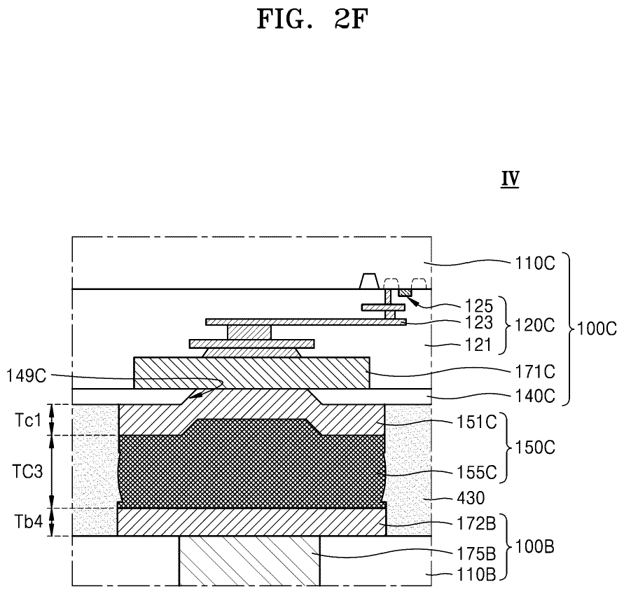

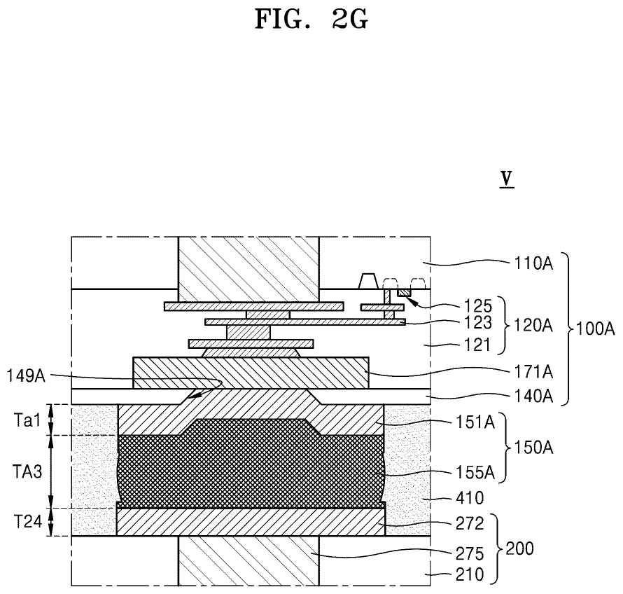

FIG. 2A is a cross-sectional view illustrating a semiconductor package 20 according to one or more example embodiments. FIG. 2B is an enlarged view of region II of FIG. 2A according to one or more example embodiments.

Referring to FIGS. 2A and 2B, the semiconductor package 20 may include a lower semiconductor chip 200, lower bumps 250, a first semiconductor chip 100A, first bonding bumps 150A, a second semiconductor chip 100B, second bonding bumps 150B, a third semiconductor chip 100C, and third bonding bumps 150C. The semiconductor package 20 may be a chip stack package. Each of the first semiconductor chip 100A and the second semiconductor chip 100B may be substantially similar to the semiconductor chip 100 described above with reference to one or more example embodiments of FIGS. 1A and 1B. Each of the first, second and third semiconductor chips 100A, 100B, and 100C may be a memory chip, such as an HBM chip. The second semiconductor chip 100B may be the same type of semiconductor chip as the first semiconductor chip 100A. For example, the second semiconductor chip 100B may have the same storage capacity and substantially the same size as the first semiconductor chip 100A. The third semiconductor chip 100C may have the same storage capacity and substantially the same width as the first and second semiconductor chips 100A and 100B. The semiconductor package 20 may further include a first insulating film 410, a second insulating film 420, and a third insulating film 430.

The first semiconductor chip 100A may include a first semiconductor substrate 110A, a first circuit layer 120A, first lower pads 171A, first through-vias 175A, and first upper pads 172A. The first semiconductor substrate 110A, the first circuit layer 120A, the first lower pads 171A, the first through-vias 175A, and the first upper pads 172A may be substantially similar to the semiconductor substrate 110, the circuit layer 120, the lower pads 171, through-vias 175, and the upper pads 172 described above with reference to one or more example embodiments according to FIGS. 1A and 1B. For example, materials, arrangement relationships, functions, and electrical connections of the first semiconductor substrate 110A, the first circuit layer 120A, the first lower pads 171A, the first through-vias 175A, and the first upper pads 172A may be substantially similar to materials, arrangement relationships, functions, and electrical connections of the semiconductor substrate 110, the circuit layer 120, the lower pads 171, through-vias 175, and the upper pads 172.

The second semiconductor chip 100B may include a second semiconductor substrate 110B, a second circuit layer 120B, second lower pads 171B, second through-vias 175B, and second upper pads 172B. The second circuit layer 120B may include a second IC 125B, a second insulating layer 121B, and second interconnections 123B, as shown in FIG. 2B. The second semiconductor substrate 110B, the second circuit layer 120B, the second lower pads 171B, the second through-vias 175B, and the second upper pads 172B may be substantially similar to the semiconductor substrate 110, the circuit layer 120, the lower pads 171, the through-vias 175, and the upper pads 172 described above with reference to one or more example embodiments of FIGS. 1A and 1B.

The second bonding bumps 150B may be located between the first semiconductor chip 100A and the second semiconductor chip 100B and may be connected to the first upper pads 172A and the second lower pads 171B. Accordingly, the second semiconductor chip 100B may be electrically connected to the first semiconductor chip 100A through the second bonding bumps 150B. The second bonding bumps 150B may be laterally spaced apart from each other. Each of the second bonding bumps 150B may include a second conductive pattern 151B and a second bonding structure 155B. The second semiconductor chip 100B may further include a second protective layer 140B as shown in FIG. 2B. The second protective layer 140B may be substantially similar to the protective layer 140 of FIG. 1B. For example, the second protective layer 140B may have a second pad opening 149B exposing a lower surface of the second lower pad 171B.

The second conductive pattern 151B may be provided in the second pad opening 149B and may cover a lower surface of a center region of the second lower pad 171B. The second conductive pattern 151B may be similar to or similar to the conductive pattern 151 described above in with reference to one or more example embodiments according to FIGS. 1A and 1B. For example, the second conductive pattern 151B may extend to a lower surface of the second protective layer 140B and may cover the lower surface of the second protective layer 140B. The second conductive pattern 151B may include a first metal. The first metal may include, for example, nickel and/or a nickel alloy. The second conductive pattern 151B may function as a barrier film but one or more example embodiments are not limited thereto.

The second bonding structure 155B may be provided between the second conductive pattern 151B and the second upper pad 172B and connected to the second conductive pattern 151B and the second upper pad 172B. The second bonding structure 155B may include an intermetallic compound (IMC) of a second metal and a solder material. According to one or more example embodiments, the second bonding structure 155B may include an intermetallic compound of at least two metals selected from copper, tin (Sn), and silver (Ag). The intermetallic compound may further include gold (Au). However, the content ratio of gold (Au) in the intermetallic compound may be less than the content ratio of the first metal and the content ratio of the solder material. For example, the content ratio of gold (Au) in the second bonding structure 155B may be less than the content ratio of copper in the second bonding structure 155B. The content ratio of gold (Au) in the second bonding structure 155B may be less than the content ratio of silver (Ag) and the content ratio of tin (Sn) in the second bonding structure 155B. According to one or more example embodiments, the intermetallic compound of certain materials does not exclude other materials or metals from being further included.

One of the second insulating films 420 may be provided in a gap region between the first and second semiconductor chips 100A and 100B to cover sidewalls of the second bonding bump 150B. For example, the one of the second insulating films 420 may cover sidewalls of the first upper pad 172A, sidewalls of the second bonding structure 155B, and sidewalls of the second conductive pattern 151B. The one of the second insulating films 420 may be apart from the second lower pad 171B. A thickness of the one of the second insulating films 420 may be equal to a gap between the first and second semiconductor chips 100A and 100B. The thickness of the one of the second insulating films 420 may be equal to the sum of a thickness Tb1 of the second conductive pattern 151B, a thickness TB3 of the second bonding structure 155B, and a thickness Ta4 of the first upper pad 172A. The second insulating films 420 may include an insulating polymer. According to one or more example embodiments, a non-conductive film may be used as the second insulating films 420.

According to one or more example embodiments, the formation of the second bonding bump 150B and a process of bonding the first semiconductor chip 100A to the second semiconductor chip 100B is described below.

FIGS. 2C and 2D are diagrams illustrating a process of bonding the first semiconductor chip 100A to the second semiconductor chip 100B according to one or more example embodiments and correspond to enlarged views of region II of FIG. 2A. In the following description, a single first upper pad 172A, a single second bonding bump 150B, and a single second lower pad 171B are described according to one or more example embodiments.

Referring to FIG. 2C, the second semiconductor chip 100B provided with a second bump 150BB may be prepared. The second bump 150BB may include a second conductive pattern 151B, a second metal pattern 152B, and a second solder ball 153B. The second conductive pattern 151B, the second metal pattern 152B, and the second solder ball 153B may be substantially similar to the conductive pattern 151, the metal pattern 152, and the solder ball 153 described above with reference to one or more example embodiments according to FIGS. 1A and 1B, respectively. For example, the second conductive pattern 151B may be provided in the second pad opening 149B and may cover a lower surface of a center region of the second lower pad 171B. The second conductive pattern 151B may include a first metal. The first metal may include, for example, nickel and/or a nickel alloy.

The second solder ball 153B may be provided on a lower surface of the second conductive pattern 151B. The second solder ball 153B may include a metal that is different from the second conductive pattern 151B. The second solder ball 153B may include a solder material.

The second metal pattern 152B may be provided between the second conductive pattern 151B and the second solder ball 153B. The second metal pattern 152B may directly contact the second conductive pattern 151B and the second solder ball 153B. A width of the second metal pattern 152B may be substantially equal to a width of the second conductive pattern 151B. The second metal pattern 152B may include a second metal. For example, the second metal may include copper and/or a copper alloy.

The first upper pad 172A may be disposed on an upper surface of the first semiconductor chip 100A and electrically connected to the first through-via 175A. The first upper pad 172A may include the same metal as the second conductive pattern 151B. For example, the first upper pad 172A may include a first metal.

The first semiconductor chip 100A may further include a first bonding pad 173A. The first bonding pad 173A may be provided on an upper surface of the first upper pad 172A and may cover the upper surface of the first upper pad 172A. The first bonding pad 173A may include a third metal that is different from the first and second metals. The third metal may include gold (Au). A thickness of the first bonding pad 173A may be less than a thickness Ta4′ of the first upper pad 172A.

According to one or more example embodiments, a maximum thickness Tb3 of the second solder ball 153B may be about 50% to about 61% of the sum of the thickness Tb1′ of the second conductive pattern 151B, a thickness Tb2 of the second metal pattern 152B, a maximum thickness Tb3 of the second solder ball 153B, and a thickness Ta4′ of the first upper pad 172A. The thickness T2 of the metal pattern 152 may be about 7% to about 9% of the sum of the thickness Tb1′ of the second conductive pattern 151B, the thickness Tb2 of the second metal pattern 152B, the maximum thickness Tb3 of the second solder ball 153B, and the thickness Ta4′ of the first upper pad 172A. The thickness Tb1′ of the second conductive pattern 151B may be about 20% to 25% of the sum of the thickness Tb1′ of the second conductive pattern 151B, the thickness Tb2 of the second metal pattern 152B, the maximum thickness Tb3 of the second solder ball 153B, and the thickness Ta4′ of the first upper pad 172A. The thickness Ta4′ of the first upper pad 172A may be about 19% to about 24% of the sum of the thickness Tb1′ of the second conductive pattern 151B, the thickness Tb2 of the second metal pattern 152B, the maximum thickness Tb3 of the second solder ball 153B, and the thickness Ta4′ of the first upper pad 172A.

The second semiconductor chip 100B may be disposed on the first semiconductor chip 100A such that the second bump 150BB is vertically aligned with the first upper pad 172A. The second bump 150BB may directly contact the first upper pad 172A. For example, the second bump 150BB may directly contact the first bonding pad 173A.

According to one or more example embodiments, one of the second insulating films 420 may be provided on a lower surface of the second semiconductor chip 100B or an upper surface of the first semiconductor chip 100A. The one of the second insulating films 420 may cover sidewalls of the second bump 150BB.

Referring to FIGS. 2D and 2B in turn, a bonding process for the second bump 150BB may be performed. The bonding process for the second bump 150BB may include applying heat to the second bump 150BB. According to one or more example embodiments, additional pressure may be applied to the second semiconductor chip 100B and the second bump 150BB. For example, the bonding process for the second bump 150BB may be a thermocompression bonding process. During the bonding process, the second solder ball 153B may be reflowed.

Under heat and pressure conditions, the second metal in the second metal pattern 152B may react with the second solder ball 153B. During the bonding process, the second metal in the second metal pattern 152B may diffuse into the second solder ball 153B as indicated by the arrows. The diffused second metal may be combined with a solder material in the second solder ball 153B to form an intermetallic compound. In addition, the solder material in the second solder ball 153B may move into the second metal pattern 152B as indicated by the arrows. The moved solder material may be combined with a second metal in the second metal pattern 152B to form an intermetallic compound. Accordingly, the second bonding structure 155B described with reference to FIG. 2B may be formed. The second bonding structure 155B may include an intermetallic compound of the second metal and the solder material.

The second conductive pattern 151B may have low reactivity to the second metal in the second metal pattern 152B and the solder material in the second solder ball 153B. Accordingly, during the bonding process, the first metal in the second conductive pattern 151B may not form an intermetallic compound. Alternatively, the first metal in the second conductive pattern 151B may form an intermetallic compound, but a proportion of the first metal in the second conductive pattern 151B that forms an intermetallic compound may be insignificant. Accordingly, after the bonding process is completed, the second conductive pattern 151B may remain. For example, the intermetallic compound may further include nickel, but the content ratio of nickel in the intermetallic compound may be small. For example, the content ratio of nickel in the second bonding structure 155B may be less than the content ratio of copper, the content ratio of tin, and the content ratio of silver (Ag) in the second bonding structure 155B. After the bonding process, the thickness of the second conductive pattern 151B (Tb1 in FIG. 2B) may be equal to or less than the thickness (Tb1′ in FIG. 2C) of the second conductive pattern 151B before the bonding process.

Because the second metal pattern 152B has high reactivity to the second solder ball (153B in FIGS. 2C and 2D), the second metal pattern 152B and the second solder ball 153B may not remain after the bonding process is completed. Accordingly, the second bonding structure (155B in FIG. 2B) may directly contact the lower surface of the second conductive pattern 151B.

The volume of the second bonding structure 155B may be different from the sum of the volume of the second metal pattern 152B and the volume of the second solder ball 153B. Although the volume of the second bonding structure 155B changes, the second insulating film 420 may well cover the sidewalls of the second bonding structure 155B. The second insulating film 420 may buffer the change in volume of the second bonding structure 155B.

As shown in FIG. 2D, the second solder ball 153B may directly contact the first bonding pad 173A. The first bonding pad 173A may include a third metal. During the bonding process, the third metal in the first bonding pad 173A may diffuse into the second solder ball 153B as indicated by the arrows. The diffused third metal may be combined with the solder material and/or the diffused second metal in the second solder ball 153B to form an intermetallic compound. In addition, the solder material in the second solder ball 153B may move into the first bonding pad 173A as indicated by the arrows. The moved solder material may be combined with the third metal in the first bonding pad 173A to form an intermetallic compound. In this case, the second bonding structure 155B described above with reference to one or more example embodiments according to FIG. 2B may include an intermetallic compound of the second metal, the third metal, and the solder material. Because the thickness of the first bonding pad 173A is small, the content ratio of the third metal in the intermetallic compound may be small. For example, the content ratio of the third metal (e.g., gold (Au)) in the second bonding structure 155B may be less than the content ratio of copper, the content ratio of silver (Au), and the content ratio of tin.

The first upper pad 172A may have low reactivity to the second bonding structure 155B or the solder material. Accordingly, during the bonding process, the first metal in the first upper pad 172A may not form an intermetallic compound. Alternatively, the third metal in the first upper pad 172A may form an intermetallic compound, but the proportion of the third metal forming an intermetallic compound may be insignificant. Accordingly, after the bonding process is completed, the first upper pad 172A may remain. The second bonding structure 155B may be in direct contact with the first upper pad 172A. After the bonding process, the thickness (Ta4 in FIG. 2B) of the first upper pad 172A may be equal to or less than the thickness (Ta4′ in FIG. 2C) of the first upper pad 172A before the bonding process.

The second bonding bump 150B of FIG. 2B may be manufactured by one or more example embodiments, as described above. The second bonding bump 150B may include the second conductive pattern 151B and the second bonding structure 155B.

When the second solder ball (153B in FIG. 2C) is bonded to the first semiconductor chip 100A and the second semiconductor chip 100B, volume shrinkage of the second solder ball 153B may occur during the operation of the semiconductor package 20. In this case, an empty space may be formed within the second solder ball 153B. As the operating time of the semiconductor package 20 increases, the volume of the empty space within the second solder ball 153B may increase. When the semiconductor package 20 operates for a long period of time, it may be difficult for the second upper pad 172B to be electrically connected to the first lower pad 171A through the second solder ball 153B due to the empty space. An electrical connection failure may occur between the first semiconductor chip 100A and the second semiconductor chip 100B.

According to one or more example embodiments, the second bonding structure 155B of the second bonding bump 150B of FIG. 2B may include an intermetallic compound. The intermetallic compound may have physical and chemical properties that are different from the second metal and solder material. When the intermetallic compound further includes a third metal, the intermetallic compound may have physicochemical properties that are different from those of the third metal. Intermetallic compounds may have excellent durability. For example, although the semiconductor package 20 operates for a long period of time, the volume of the second bonding structure 155B may not change or the volume of the second bonding structure 155B may not change significantly. Accordingly, although the semiconductor package 20 operates for a long period of time, the second semiconductor chip 100B may be well connected to the first semiconductor chip 100A through the second bonding structure 155B. The semiconductor package 20 according to one or more example embodiments may have long-term reliability.

According to one or more example embodiments, the gap between the first semiconductor chip 100A and the second semiconductor chip 100B may be from about 3 μm to 7 μm. The gap between the first semiconductor chip 100A and the second semiconductor chip 100B may be equal to the sum of the thicknesses Ta4 of the first upper pad 172A, the thickness TB3 of the second bonding structure 155B, and the thickness Tb1 of the second conductive pattern 151B. Because the gap between the first semiconductor chip 100A and the second semiconductor chip 100B is 7 μm or less, the semiconductor package 20 may be miniaturized. In addition, heat occurring in the first semiconductor chip 100A or the second semiconductor chip 100B may be rapidly dissipated. Because the sum of the thickness Ta4 of the first upper pad 172A, the thickness TB3 of the second bonding structure 155B, and the thickness Tb1 of the second conductive pattern 151B is 3 μm or more, the second bonding structure 155B may be firmly combined with the first upper pad 172A and the second lower pad 171B. In addition, the difficulty of the manufacturing process of the semiconductor package 20 may be reduced.

After the bonding process is completed, if a portion of the second solder ball 153B of FIG. 2C remains between the second bonding structure 155B and the first upper pad 172A of FIG. 2B, volume shrinkage of the second solder ball 153B may occur during long-term operation of the semiconductor package 20.

According to one or more example embodiments, before the bonding process, the proportions of the thickness Tb1 of the second conductive pattern 151B, the thickness Tb2 of the second metal pattern 152B, the maximum thickness Tb3 of the second solder ball 153B, and the thickness Ta4′ of the first upper pad 172A of FIG. 2C satisfy the conditions described above, and thus, the second bonding structure 155B of FIG. 2B may be in direct contact with the second conductive pattern 151B and the second conductive pattern 172A after the bonding process. According to one or more example embodiments, the second metal pattern 152B or the second solder ball 153B may not remain. Accordingly, although the semiconductor package 20 operates for a long period of time, a change in the volume of the second bonding structure 155B may be further prevented. The semiconductor package 20 may have improved operational reliability and durability.

According to one or more example embodiments, the thickness TB3 of the second bonding structure 155B in FIG. 2B may be about 47% to about 54% of the sum of the thickness Tb1 of the second conductive pattern 151B, the thickness TB3 of the second bonding structure 155B, and the thickness Ta4 of the first upper pad 172A. The thickness TB3 of the second bonding structure 155B may be about 47% to about 54% of the gap between the first semiconductor chip 100A and the second semiconductor chip 100B. Because the thickness TB3 of the second bonding structure 155B satisfies the above conditions, a reduction in volume of the second bonding structure 155B may be prevented although the semiconductor package 20 operates for a long period of time. Long-term reliability of the semiconductor package 20 may be improved.

The thickness Tb1 of the second conductive pattern 151B may be about 24% to about 28% of the sum of the thickness Tb1 of the second conductive pattern 151B, the thickness TB3 of the second bonding structure 155B, and the thickness Ta4 of the first upper pad 172A. The thickness Ta4 of the first upper pad 172A may be about 24% to 28% of the sum of the thickness Tb1 of the second conductive pattern 151B, the thickness TB3 of the second bonding structure 155B, and the thickness Ta4 of the first upper pad 172A. The thickness Tb1 of the second conductive pattern 151B and the thickness Ta4 of the first upper pad 172A may each be about 24% to about 28% of the gap between the first semiconductor chip 100A and the second semiconductor chip 100B. Because the thickness Tb1 of the second conductive pattern 151B and the thickness Ta4 of the first upper pad 172A satisfy the above conditions, the second conductive pattern 151B and the first upper pad 172A may remain without reacting with the second bonding structure 155B although the semiconductor package 20 operates for a long period of time. A change in volume of the second bonding structure 155B may be prevented. The second conductive pattern 151B and the first upper pad 172A may prevent the second bonding structure 155B from moving. Accordingly, the long-term reliability of the semiconductor package 20 may be further improved.

The second semiconductor chip 100B, the second bonding bump 150B, the second conductive pattern 151B, and the second bonding structure 155B may be referred to as an upper semiconductor chip, an upper bonding bump, an upper conductive pattern, and an upper bonding structure, respectively. According to one or more example embodiments, the second bonding bumps 150B between the second semiconductor chips 100B and a connection between the second semiconductor chips 100B are described.

FIG. 2E is an enlarged view of region III of FIG. 2A.

Referring to FIGS. 2A and 2E, the semiconductor package 20 may include a plurality of second semiconductor chips 100B. The second semiconductor chips 100B may be stacked on the first semiconductor chip 100A. The second bonding bumps 150B may be located between the second semiconductor chips 100B and may be electrically connected to the second semiconductor chips 100B. The second bonding bumps 150B may be laterally spaced apart from each other. In the description of one or more example embodiments according to FIG. 2E, unless otherwise specified, the second bonding bumps 150B may indicate second bonding bumps 150B between the second semiconductor chips 100B. In addition, in the description of one or more example embodiments according to FIG. 2E, unless otherwise specified, any component may refer to the corresponding component shown in FIG. 2E. According to one or more example embodiments, for simplicity of description, a single second bonding bump 150B is described.

Adjacent second semiconductor chips 100B may include a second lower semiconductor chip 101B and a second upper semiconductor chip 102B, as shown in FIG. 2E. The second upper semiconductor chip 102B may be disposed on the second lower semiconductor chip 101B. The second bonding bumps 150B may include a second conductive pattern 151B and a second bonding structure 155B. The second conductive pattern 151B and the second bonding structure 155B may be substantially similar to those described above in one or more example embodiments according to FIG. 2B. Formation of the second bonding structure 155B may be performed by the method described above in one or more example embodiments according to FIGS. 2C and 2D. The second bonding structure 155B may include an intermetallic compound. The intermetallic compound may be substantially similar to that described above in one or more example embodiments according to FIG. 2B. However, the second bonding structure 155B may be combined with the second upper pad 172B of the second lower semiconductor chip 101B.

According to one or more example embodiments, the thickness TB3 of the second bonding structure 155B may be about 47% to about 54% of the sum of the thickness Tb1 of the second conductive pattern 151B, the thickness TB3 of the second bonding structure 155B, and the thickness Tb4 of the second upper pad 172B. The sum of the thickness Tb1 of the second conductive pattern 151B, the thickness TB3 of the second bonding structure 155B, and the thickness Tb4 of the second upper pad 172B may be equal to a gap between the second lower semiconductor chip 101B and the second upper semiconductor chip 102B. Because the thickness TB3 of the second bonding structure 155B satisfies the above conditions, the formation of an empty space within the second bonding structure 155B may be prevented although the semiconductor package 20 operates for a long period of time. Long-term reliability of the semiconductor package 20 may be improved.

The thickness Tb1 of the second conductive pattern 151B may be about 24% to about 28% of the sum of the thickness Tb1 of the second conductive pattern 151B, the thickness TB3 of the second bonding structure 155B, and the thickness Tb4 of the second upper pad 172B. The thickness Tb4 of the second upper pad 172B may be 24% to 28% of the sum of the thickness Tb1 of the second conductive pattern 151B, the thickness TB3 of the second bonding structure 155B, and the thickness Tb4 of the second upper pad 172B.

According to one or more example embodiments, a gap between the second semiconductor chips 100B may be about 3 μm to about 7 μm. The gap between the second semiconductor chips 100B may be equal to the sum of the thickness Tb4 of the second upper pad 172B, the thickness Tb3 of the second bonding structure 155B, and the thickness Tb1 of the second conductive pattern 151B. Because the gap between the second semiconductor chips 100B is about 7 μm or less, the semiconductor package 20 may be miniaturized and may have improved thermal characteristics. Because the sum of the thickness Tb4 of the second upper pad 172B, the thickness TB3 of the second bonding structure 155B, and the thickness Tb1 of the second conductive pattern 151B is about 3 μm or more, the second bonding structure 155B may be firmly combined with the second upper pad 172B and the second lower pad 171B.

Another one of the second insulating films 420 may be provided in the gap region between the second semiconductor chips 100B to cover the sidewalls of the corresponding second bonding structure 155B. For example, the other second insulating film 420 may cover sidewalls of the second upper pad 172B, sidewalls of the second bonding structure 155B, and sidewalls of the second conductive pattern 151B. The other second insulating film 420 may be apart from the second lower pad 171B. A thickness of the other second insulating film 420 may be equal to the gap between the second semiconductor chips 100B. The thickness of the other second insulating film 420 may be equal to the sum of the thickness Tb1 of the second conductive pattern 151B, the thickness TB3 of the second bonding structure 155B, and the thickness Tb4 of the second upper pad 172B.

Referring back to FIG. 2A, the number of stacked second semiconductor chips 100B may vary. For example, the semiconductor package 20 may include a single second semiconductor chip 100B. In contrast, according to one or more example embodiments, the semiconductor package 20 may include three or more second semiconductor chips 100B.

The third semiconductor chip 100C may be similar to the semiconductor chip 100 described above with reference to one or more example embodiments according to FIGS. 1A and 1B. For example, the third semiconductor chip 100C may include a third semiconductor substrate 110C, a third circuit layer 120C, and third lower pads 171C. The third semiconductor substrate 110C, the third circuit layer 120C, and the third lower pads 171C may be substantially and respectively similar to the semiconductor substrate 110, the circuit layer 120, and the lower pads 171 described above with reference to one or more example embodiments of FIGS. 1A and 1B. However, the third semiconductor chip 100C may not include the through-vias 175 and upper pads 172 as described above with reference to one or more example embodiments according to FIGS. 1A and 1B.

The third semiconductor chip 100C may be the same type of semiconductor chip as the first and second semiconductor chips 100A and 100B. For example, the third semiconductor chip 100C may have the same storage capacity as the storage capacity of the first semiconductor chip 100A and the storage capacity of the second semiconductor chips 100B. However, the thickness of the third semiconductor chip 100C may be greater than the thickness of the first semiconductor chip 100A and the second semiconductor chip 100B. For example, the thickness of the third semiconductor substrate 110C may be greater than the thickness of the first semiconductor substrate 110A and the thickness of the second semiconductor substrate 110B.

The third semiconductor chip 100C may be disposed on the uppermost second semiconductor chip 100B. The third bonding bumps 150C may be located between the uppermost second semiconductor chip 100B and the third semiconductor chip 100C and may be connected to the corresponding second upper pads 172B and third lower pads 171C. Accordingly, the third semiconductor chip 100C may be electrically connected to the uppermost second semiconductor chip 100B through the third bonding bumps 150C. The third bonding bumps 150C may be laterally spaced apart from each other. According to one or more example embodiments, the connection between the uppermost second semiconductor chip 100B and the third semiconductor chip 100C and the third bonding bump 150C are described herein.

FIG. 2F is an enlarged view of region IV of FIG. 2A. According to one or more example embodiments, in the description of the third bonding bumps 150C and the bonding between the uppermost second semiconductor chip 100B and the third semiconductor chip 100C, unless otherwise specified, the second upper pads 172B may refer to the second upper pads 172B of the uppermost second semiconductor chip 100B. According to one or more example embodiments, for simplicity, a single second upper pad 172B, a single third bonding bump 150C, and a single third lower pad 171C are described herein.

Referring to FIGS. 2A and 2F, the third semiconductor chip 100C may further include a third protective layer 140C. The third protective layer 140C may be substantially similar to the protective layer 140 of FIG. 1B. For example, the third protective layer 140C may have a third pad opening 149C exposing a lower surface of the third lower pad 171C.

Each of the third bonding bumps 150C may include a third conductive pattern 151C and a third bonding structure 155C. The third conductive pattern 151C may be provided in the third pad opening 149C to cover a lower surface of a center region of the third lower pad 171C. The third conductive pattern 151C may be similar to or similar to the second conductive pattern 151B described above with reference to one or more example embodiments according to FIG. 2B. For example, the third conductive pattern 151C may extend to a lower surface of the third protective layer 140C and cover the lower surface of the third protective layer 140C. The third conductive pattern 151C may include a first metal. The first metal may include, for example, nickel and/or a nickel alloy. The third conductive pattern 151C may function as a barrier film but is not limited thereto.

The third bonding structure 155C may be provided between the third conductive pattern 151C and the second upper pad 172B and may be connected to the third conductive pattern 151C and the second upper pad 172B. The third bonding structure 155C may directly contact the third conductive pattern 151C and the second upper pad 172B. The third bonding structure 155C may include an intermetallic compound. The intermetallic compound included in the third bonding structure 155C may be substantially similar to that described above with reference to one or more example embodiments of the intermetallic compound of the second bonding structure 155B. For example, the intermetallic compound may include an intermetallic compound of a second metal and a solder material. According to one or more example embodiments, the third bonding structure 155C may include an intermetallic compound of at least two metals selected from copper, tin (Sn) and silver (Ag). The intermetallic compound may further include a third metal. For example, the intermetallic compound may include an intermetallic compound of the second metal, the third metal, and the solder material. The third metal may include gold (Au). However, the content ratio of gold (Au) in the intermetallic compound may be less than the content ratio of copper, the content ratio of silver (Ag), and the content ratio of tin (Sn). The intermetallic compound may further include the first metal (e.g., nickel and/or a nickel alloy). However, the content ratio of the first metal in the intermetallic compound may be less than the content ratio of copper, the content ratio of silver (Ag), and the content ratio of tin (Sn).

According to one or more example embodiments, a thickness TC3 of the third bonding structure 155C may be about 47% to about 54% of the sum of the thickness Tc1 of the third conductive pattern 151C, the thickness TC3 of the third bonding structure 155C, and the thickness Tb4 of the second upper pad 172B. Because the thickness TC3 of the third bonding structure 155C satisfies the above conditions, the formation of an empty space within the third bonding structure 155C may be prevented although the semiconductor package 20 operates for a long period of time. Long-term reliability of the semiconductor package 20 may be improved.

The thickness Tc1 of the third conductive pattern 151C may be about 24% to about 28% of the sum of the thickness Tc1 of the third conductive pattern 151C, the thickness TC3 of the third bonding structure 155C, and the thickness Tb4 of the second upper pad 172B. The thickness Tb4 of the second upper pad 172B may be about 24% to about 28% of the sum of the thickness Tc1 of the third conductive pattern 151C, the thickness TC3 of the third bonding structure 155C, and the thickness Tb4 of the second upper pad 172B. Because the thickness Tc1 of the third conductive pattern 151C and the thickness Tb4 of the second upper pad 172B satisfy the above conditions, the long-term reliability of the semiconductor package 20 may be improved.

A gap between the uppermost second semiconductor chip 100B and the third semiconductor chip 100C may be about 3 μm to about 7 μm. A gap between the uppermost second semiconductor chip 100B and the third semiconductor chip 100C may be equal to the sum of the thickness Tb4 of the second upper pad 172B, the thickness TC3 of the third bonding structure 155C, and the thickness Tc1 of the third conductive pattern 151C. Because the gap between the uppermost second semiconductor chip 100B and the third semiconductor chip 100C is about 7 μm or less, the semiconductor package 20 may be miniaturized and exhibit improved thermal characteristics. Because the gap between the uppermost second semiconductor chip 100B and the third semiconductor chip 100C is about 3 μm or more, the third bonding structure 155C may be firmly combined with the second upper pad 172B and the third lower pad 171C.

The third insulating film 430 may be provided on the lower surface of the third semiconductor chip 100C to cover sidewalls of the third bonding bumps 150C. For example, the third insulating film 430 may be provided in a gap region between the second semiconductor chip 100B and the third semiconductor chip 100C to seal the third bonding bumps 150C. The third insulating film 430 may cover sidewalls of the second upper pad 172B, sidewalls of the third bonding structure 155C, and sidewalls of the third conductive pattern 151C and may be apart from the third lower pad 171C. A thickness of the third insulating film 430 may be equal to the gap between the second semiconductor chip 100B and the third semiconductor chip 100C. The thickness of the third insulating film 430 may be equal to the sum of the thickness Tb4 of the second upper pad 172B, the thickness TC3 of the third bonding structure 155C, and the thickness Tc1 of the third conductive pattern 151C. The third insulating film 430 may include an insulating polymer. According to one or more example embodiments, a non-conductive film may be used as the third insulating film 430. The third insulating film 430 may include the same material as that of the second insulating film 420 but is not limited thereto.

Referring back to FIG. 2A, the lower semiconductor chip 200 may be provided on a lower surface of the first semiconductor chip 100A. A width of the lower semiconductor chip 200 may be greater than widths of the first, second and third semiconductor chips 100A, 100B, and 100C. The lower semiconductor chip 200 may be a different type of semiconductor chip from the first, second and third semiconductor chips 100A, 100B, and 100C. For example, the lower semiconductor chip 200 may be a logic chip or a controller chip.

The lower semiconductor chip 200 may include a fourth semiconductor substrate 210, a fourth circuit layer 220, fourth lower pads 271, fourth through-vias 275, and fourth upper pads 272. The fourth semiconductor substrate 210, the fourth circuit layer 220, the fourth lower pads 271, the fourth through-vias 275, and the fourth upper pads 272 may be substantially similar to the semiconductor substrate 110, the circuit layer 120, lower pads 171, the through-vias 175, and the upper pads 172 described above with reference to one or more example embodiments of FIGS. 1A and 1B. The fourth upper pads 272 may be conductive pads.

The first semiconductor chip 100A may be disposed on an upper surface of the lower semiconductor chip 200. The first bonding bumps 150A may be located between the lower semiconductor chip 200 and the first semiconductor chip 100A and may be connected to the corresponding fourth upper pads 272 and first lower pads 171A. Accordingly, the first semiconductor chip 100A may be electrically connected to the lower semiconductor chip 200 through the first bonding bumps 150A. The first bonding bumps 150A may be laterally spaced apart from each other. Each of the first bonding bumps 150A may include a first conductive pattern 151A and a first bonding structure 155A. According to one or more example embodiments, the connection between the lower semiconductor chip 200 and the first semiconductor chip 100A and the first bonding bumps 150A are described.

FIG. 2G is an enlarged view of region V of FIG. 2A. According to one or more example embodiments, for simplicity, a single fourth upper pad 272, a single first bonding bump 150A, and a single first lower pad 171A are described.

The first semiconductor chip 100A may further include a first protective layer 140A. The first protective layer 140A may be substantially similar to the protective layer 140 of FIG. 1B. For example, the first protective layer 140A may have a first pad opening 149A exposing a lower surface of the first lower pad 171A.

The first conductive pattern 151A may be provided in the first pad opening 149A to cover a lower surface of a center region of the first lower pad 171A. The first conductive pattern 151A may be similar to or similar to the second conductive pattern 151B described above with reference to one or more example embodiments according to FIG. 2B. For example, the first conductive pattern 151A may extend to a lower surface of the first protective layer 140A and cover the lower surface of the first protective layer 140A. The first conductive pattern 151A may include a first metal. The first metal may include, for example, nickel and/or a nickel alloy. The first conductive pattern 151A may function as a barrier film but is not limited thereto.

The first bonding structure 155A may be provided between the first conductive pattern 151A and the fourth upper pad 272 and may be connected to the first conductive pattern 151A and the fourth upper pad 272. The first bonding structure 155A may directly contact the first conductive pattern 151A and the fourth upper pad 272. The first bonding structure 155A may include an intermetallic compound. The intermetallic compound included in the first bonding structure 155A may be substantially similar to that described above with reference to one or more example embodiments of the intermetallic compound of the second bonding structure 155B. The intermetallic compound may include an intermetallic compound of a second metal and a solder material. According to one or more example embodiments, the first bonding structure 155A may include an intermetallic compound of at least two metals selected from copper (Cu), tin (Sn), and silver (Ag). The intermetallic compound may further include a third metal. For example, the intermetallic compound may include an intermetallic compound of the second metal, the third metal, and the solder material. The third metal may include gold (Au). However, the content ratio of gold (Au) in the intermetallic compound may be less than the content ratio of copper, the content ratio of silver (Ag), and the content ratio of tin (Sn). The intermetallic compound may further include a first metal. However, the content ratio of the first metal in the intermetallic compound may be less than the content ratio of copper, the content ratio of silver (Ag), and the content ratio of tin (Sn).

According to one or more example embodiments, a thickness TA3 of the first bonding structure 155A may be about 47% to about 54% of the sum of the thickness Tal of the first conductive pattern 151A, the thickness TA3 of the first bonding structure 155A, and a thickness T24 of the fourth upper pad 272. Because the thickness Tal of the first conductive pattern 151A and the thickness TA3 of the first bonding structure 155A satisfy the above conditions, the formation of an empty space having an excessively large volume in the first bonding structure 155A may be prevented although the semiconductor package 20 operates for a long period of time. Long-term reliability of the semiconductor package 20 may be improved.

The thickness Tal of the first conductive pattern 151A may be about 24% to about 28% of the sum of the thickness Tal of the first conductive pattern 151A, the thickness TA3 of the first bonding structure 155A, and the thickness of the fourth upper pad 272. The thickness T24 of the fourth upper pad 272 may be about 24% to about 28% of the sum of the thickness Tal of the first conductive pattern 151A, the thickness TA3 of the first bonding structure 155A, and the thickness of the fourth upper pad 272. Because the thickness Tal of the first conductive pattern 151A and the thickness T24 of the fourth upper pad 272 satisfy the above conditions, the long-term reliability of the semiconductor package 20 may be improved.

A gap between the lower semiconductor chip 200 and the first semiconductor chip 100A may be about 3 μm to about 7 μm. The gap between the lower semiconductor chip 200 and the first semiconductor chip 100A may be equal to the sum of the thickness T24 of the fourth upper pad 272, the thickness TA3 of the first bonding structure 155A, and thickness Tal of the first lower pad 171A. Because the gap between the lower semiconductor chip 200 and the first semiconductor chip 100A is about 7 μm or less, the semiconductor package 20 may be miniaturized and exhibit improved thermal characteristics. Because the gap between the lower semiconductor chip 200 and the first semiconductor chip 100A is about 3 μm or more, the first bonding structure 155A may be firmly combined with the fourth upper pad 272 and the first lower pad 171A.

The first insulating film 410 may be provided in a gap region between the lower semiconductor chip 200 and the first semiconductor chip 100A to cover a sidewall of the first bonding bump 150A. The thickness of the first insulating film 410 may be equal to the gap between the lower semiconductor chip 200 and the first semiconductor chip 100A. A thickness of the first insulating film 410 may be equal to the sum of the thickness T24 of the fourth upper pad 272, the thickness TA3 of the first bonding structure 155A, and the thickness Tal of the first conductive pattern 151A. The first insulating film 410 may include an insulating polymer. According to one or more example embodiments, a non-conductive film may be used as the first insulating film 410. The first insulating film 410 may include the same material as those of the second insulating film 420 and the third insulating film 430 but is not limited thereto.

Referring back to FIG. 2A, a molding film 400 may be provided on an upper surface of the lower semiconductor chip 200 to cover sidewalls of the first semiconductor chip 100A, sidewalls of the second semiconductor chips 100B, and side walls of the third semiconductor chip 100C. The molding film 400 may cover sidewalls of the first, second and third insulating films 410, 420, and 430. The molding film 400 may further cover an upper surface of the third semiconductor chip 100C. Alternatively, the molding film 400 may expose the upper surface of the third semiconductor chip 100C. The molding film 400 may include an insulating polymer, such as epoxy molding compound (EMC).

Lower bumps 250 may be provided on a lower surface of the lower semiconductor chip 200. For example, the lower bumps 250 may be provided on a lower surfaces of the plurality of fourth lower pads 271, respectively. Each of the lower bumps 250 may include a lower metal pattern 252, a lower conductive pattern 251, and a lower solder ball 253. The lower metal pattern 252 may be provided on a lower surface of the corresponding fourth lower pads 271. The lower metal pattern 252 may directly contact the lower surfaces of the fourth lower pads 271. The lower metal pattern 252 may include a different metal from first, second and third conductive patterns 151A, 151B, and 151C. The lower metal pattern 252 may include a second metal. The second metal may include copper, for example. Unlike shown, the lower metal pattern 252 may have a pillar shape.

A lower solder ball 253 may be provided on a lower surface of the lower metal pattern 252. The lower solder ball 253 may include a different metal from the lower metal pattern 252. The lower solder ball 253 may include a solder material.

The lower conductive pattern 251 may be provided between the lower metal pattern 252 and the lower solder ball 253. The lower conductive pattern 251 may directly contact the lower metal pattern 252 and the lower solder ball 253. A width of the lower conductive pattern 251 may be substantially equal to a width of the lower metal pattern 252. The lower conductive pattern 251 may include the same metal as those of the first, second and third conductive patterns 151A, 151B, and 151C and the fourth upper pads 272. The lower conductive pattern 251 may include a first metal. The first metal may include nickel and/or a nickel alloy. The lower conductive pattern 251 may function as a barrier film but is not limited thereto.

Unlike one or more example embodiments shown in the drawings, each of the lower bumps 250 may not include the lower conductive pattern 251. In this case, the lower solder ball 253 may directly contact a lower surface of the lower metal pattern 252.

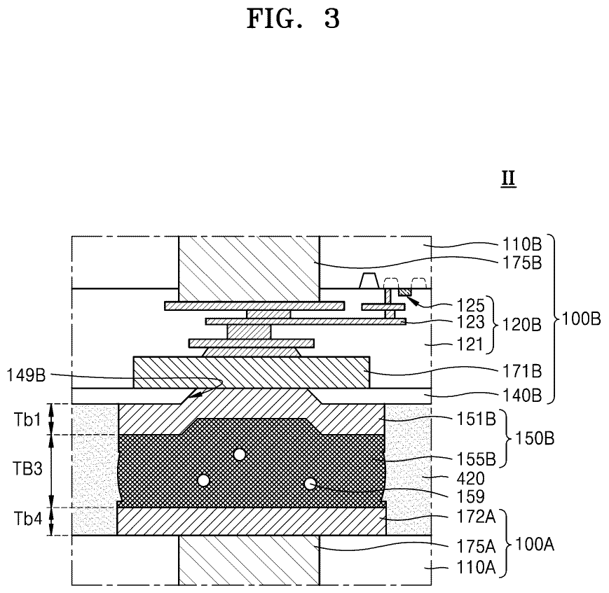

FIG. 3 is a diagram illustrating the second bonding structure 155B according to one or more example embodiments, and corresponds to an enlarged view of region II of FIG. 2A.

Referring to FIG. 3, the second bonding structure 155B may be provided between the second conductive pattern 151B and the first upper pad 172A. The first upper pad 172A, the second bonding structure 155B, and the second conductive pattern 151B may be substantially similar to those described above with reference to one or more example embodiments. For example, the second bonding structure 155B may include an intermetallic compound.

The second bonding structure 155B may have a void therein. The void may be an empty space in a vacuum state. According to one or more example embodiments, the void may be an empty space occupied by air. The void may have a relatively small diameter and volume. Although the void is provided, the second bonding structure 155B may electrically connect the first upper pad 172A to the second conductive pattern 151B.

One or more example embodiments may be combined with each other. For example, the second bonding structure 155B of FIG. 2E, the third bonding structure 155C of FIG. 2F, and the first bonding structure 155A of FIG. 2G may each have voids as described above with reference to one or more example embodiments according to FIG. 3. One or more example embodiments are not limited thereto and may be combined variably.

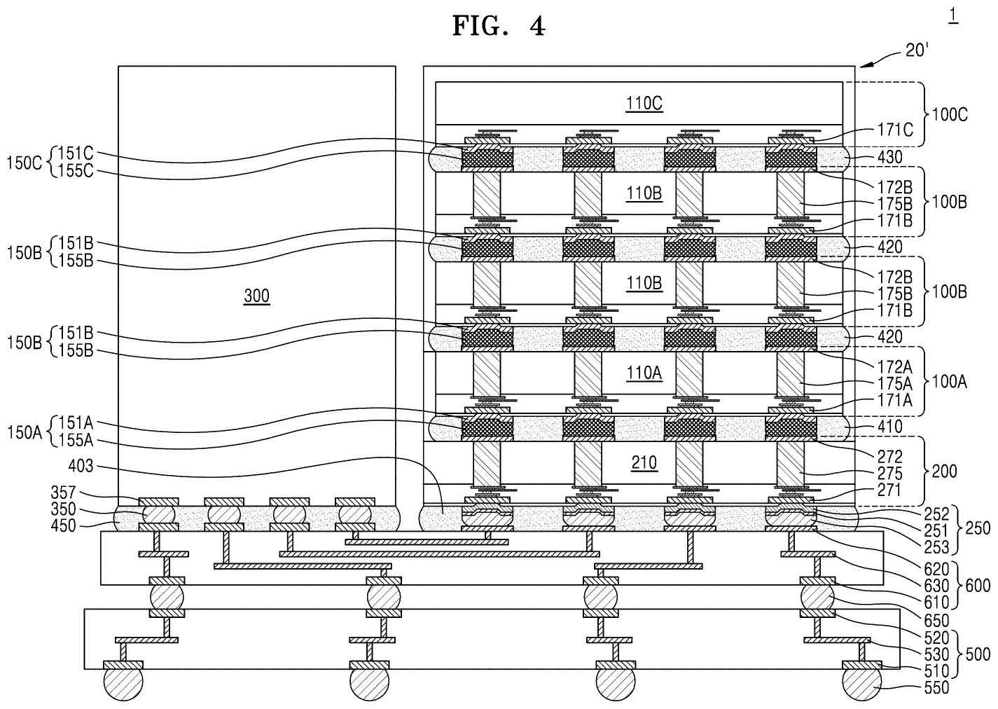

FIG. 4 is a diagram illustrating a semiconductor package 1 according to one or more example embodiments.

Referring to FIG. 4, the semiconductor package 1 may include solder ball terminals 550, a package substrate 500, an interposer substrate 600, a semiconductor device 300, and a chip stack package 20′.

The package substrate 500 may include lower substrate pads 510, substrate interconnections 530, and upper substrate pads 520. For example, a printed circuit board may be used as the package substrate 500. The upper substrate pads 520 and the lower substrate pads 510 may be provided on upper and lower surfaces of the package substrate 500, respectively. The substrate interconnections 530 are provided within the package substrate 500 and may be connected to the upper substrate pads 520 and the lower substrate pads 510. Accordingly, the lower substrate pads 510 may be connected to the upper substrate pads 520 through the substrate interconnections 530. Being electrically connected to the package substrate 500 may refer to being electrically connected to at least one of the substrate interconnections 530. The lower substrate pads 510, substrate interconnections 530, and upper substrate pads 520 may include metal, such as copper, aluminum, tungsten, and/or titanium.

The solder ball terminals 550 may be provided on a lower surface of the package substrate 500 and may be electrically connected to the lower substrate pads 510. External electrical signals may be transmitted to the solder ball terminals 550. The solder ball terminals 550 may include a solder material.

The interposer substrate 600 may be provided on the package substrate 500. The interposer substrate 600 may include lower interposer pads 610, interposer interconnections 630, and upper interposer pads 620. The upper interposer pads 620 may be provided on an upper surface of the interposer substrate 600. The interposer interconnections 630 are provided in the interposer substrate 600 and may be connected to the upper interposer pads 620. Being electrically connected to the interposer substrate 600 may refer to being electrically connected to at least one of the interposer interconnections 630. The lower interposer pads 610 may be provided on a lower surface of the interposer substrate 600 and may be electrically connected to the interposer interconnections 630. Accordingly, the lower interposer pads 610 may be connected to the upper interposer pads 620 through the interposer interconnections 630. The lower interposer pads 610 and the interposer interconnections 630 may include metal. The upper interposer pads 620 may include, for example, a first metal. The first metal may include nickel and/or a nickel alloy. According to one or more example embodiments, the upper interposer pads 620 may include copper, aluminum, tungsten, and/or titanium.

The interposer solder balls 650 may be located between the package substrate 500 and the interposer substrate 600 and may be connected to the upper substrate pads 520 and lower interposer pads 610. A pitch of the interposer solder balls 650 may be less than a pitch of the solder ball terminals 550. The interposer solder balls 650 may include a solder material.

A chip stack package 20′ may be disposed on an upper surface of the interposer substrate 600. The semiconductor package 20 described above with reference to one or more example embodiments according to FIG. 2A may be used as the chip stack package 20′. For example, the chip stack package 20′ may include the lower semiconductor chip 200, the lower bumps 250, the first semiconductor chip 100A, the first bonding bumps 150A, the second semiconductor chip 100B, the second bonding bumps 150B, the third semiconductor chip 100C, and the third bonding bumps 150C. The lower semiconductor chip 200, the lower bumps 250, the first semiconductor chip 100A, the first bonding bumps 150A, the second semiconductor chip 100B, the second bonding bumps 150B, the third semiconductor chip 100C, and the third bonding bumps 150C may be substantially similar to those described above with reference to one or more example embodiments according to FIGS. 2A, 2B, 2C, 2D, 2E, 2F and 2G or FIG. 3.

The lower bumps 250 may be disposed on the upper interposer pads 620 and may be connected to the upper interposer pads 620. For example, the lower solder ball 253 may be bonded to an upper surface of a corresponding upper interposer pad 620. Because the upper interposer pads 620 include a first metal, the lower solder ball 253 may not form an intermetallic compound with any of the upper interposer pads 620. Alternatively, although an intermetallic compound is formed between the lower solder ball 253 and one of the upper interposer pads 620, the intermetallic compound being formed may be insignificant. Accordingly, after the chip stack package 20′ is mounted on the interposer substrate 600, the lower solder ball 253 may include a solder material. The lower metal pattern 252 and the lower conductive pattern 251 may be located between the lower solder ball 253 and the corresponding fourth lower pad 271. The first, second and third semiconductor chips 100A, 100B, and 100C and the lower semiconductor chip 200 may be electrically connected to the interposer substrate 600 through the lower bumps 250. A pitch of the lower bumps 250 may be less than a pitch of the interposer solder balls 650.

The semiconductor package 1 may further include a first underfill film 403. The first underfill film 403 may be provided between the interposer substrate 600 and the chip stack package 20′ to cover sidewalls of the lower bumps 250. The first underfill film 403 may include an insulating polymer, such as an epoxy polymer, but is not limited thereto.

The semiconductor device 300 is provided on the interposer substrate 600 and may be laterally apart from the chip stack package 20′. For example, the first, second and third semiconductor chips 100A, 100B, and 100C and the lower semiconductor chip 200 may be arranged to be laterally apart from the semiconductor device 300. According to one or more example embodiments, the semiconductor device 300 may include a graphics processing unit (GPU) or a central processing unit (CPU). The semiconductor device 300 may be electrically connected to the chip stack package 20′ through the interposer substrate interconnections 630.

The semiconductor device 300 may include ICs and chip pads 357. The ICs may be provided within the semiconductor device 300. The chip pads 357 may be provided on a lower surface of the semiconductor device 300 and may be electrically connected to the ICs of the semiconductor device 300.

Solder bumps 350 may be located between the interposer substrate 600 and the semiconductor device 300. For example, the solder bumps 350 may be connected to the chip pads 357 of the semiconductor device 300 and the corresponding upper interposer pads 620. The semiconductor device 300 may be electrically connected to the chip stack package 20′ or the solder ball terminals 550 through the interposer substrate 600. The solder bumps 350 may include a solder material. According to one or more example embodiments, the solder bumps 350 may further include pillar patterns. A pitch of the solder bumps 350 may be less than a pitch of the interposer solder balls 650.

The semiconductor package 1 may further include a second underfill film 450. The second underfill film 450 may be provided between the interposer substrate 600 and the semiconductor device 300 to cover sidewalls of the solder bumps 350. The second underfill film 450 may include an insulating polymer, such as an epoxy polymer, but is not limited thereto.

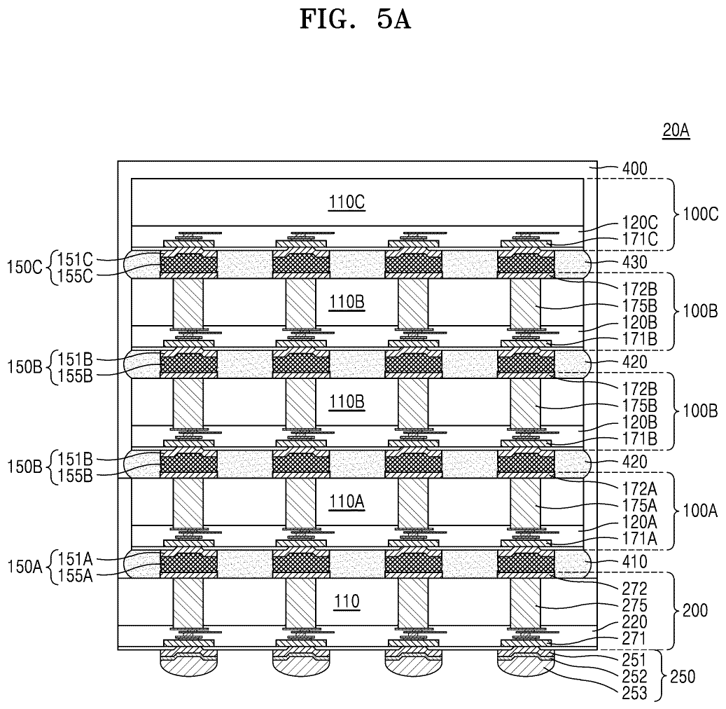

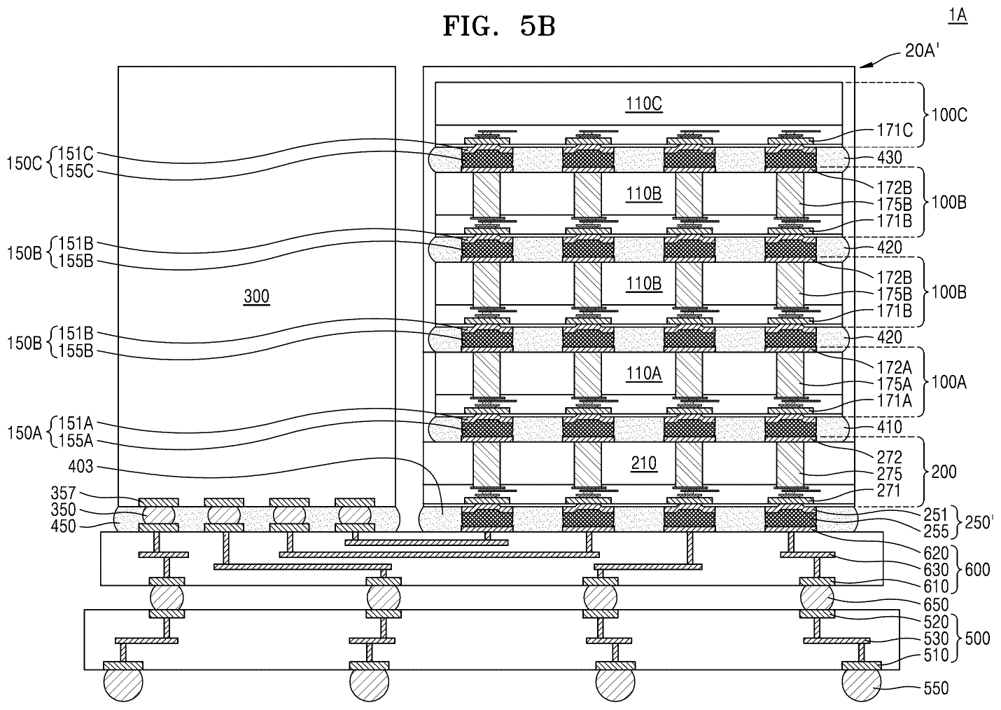

FIG. 5A is a diagram illustrating a semiconductor package 20A according to one or more example embodiments.

Referring to FIG. 5A, the semiconductor package 20A may include the lower semiconductor chip 200, the lower bumps 250, the first semiconductor chip 100A, the first bonding bumps 150A, the second semiconductor chip 100B, the second bonding bumps 150B, the third semiconductor chip 100C, and the third bonding bumps 150C. The semiconductor package 20A may include a chip stack package. The lower semiconductor chip 200, first semiconductor chip 100A, first bonding bumps 150A, second semiconductor chip 100B, second bonding bumps 150B, third semiconductor chip 100C, and third bonding bumps 150C may be substantially similar to those described above with reference to one or more example embodiments according to FIGS. 2A, 2B, 2C, 2D, 2E, 2F and 2G or FIG. 3.

Each of the lower bumps 250 may include a lower conductive pattern 251, a lower metal pattern 252, and a lower solder ball 253. However, unlike FIG. 2A, according to one or more example embodiments shown in FIG. 5A, the lower metal pattern 252 may be located between the lower conductive pattern 251 and the lower solder ball 253 and may directly contact the lower conductive pattern 251 and the lower solder ball 253. The lower metal pattern 252 may include copper. The lower conductive pattern 251 may include nickel.

A maximum thickness of the lower solder ball 253 may be about 50% to about 61% of the sum of the thickness of the lower conductive pattern 251, the thickness of the lower metal pattern 252, a maximum thickness of the lower solder ball 253, and the thickness of the fourth upper pad 272. The thickness T2 of the metal pattern 152 may be about 7% to about 9% of the sum of the thickness of the lower conductive pattern 251, the thickness of the lower metal pattern 252, the maximum thickness of the lower solder ball 253, and the thickness of the fourth upper pad 272. The thickness of the lower conductive pattern 251 may be about 20% to about 25% of the sum of the thickness of the lower conductive pattern 251, the thickness of the lower metal pattern 252, the maximum thickness of the lower solder ball 253, and the thickness of the fourth upper pad 272. The thickness of the fourth upper pad 272 may be about 19% to about 24% of the sum of the thickness of the lower conductive pattern 251, the thickness of the lower metal pattern 252, the maximum thickness of the lower solder ball 253, and the thickness of the fourth upper pad 272.

FIG. 5B is a diagram illustrating a semiconductor package 1A according to one or more example embodiments.

Referring to FIG. 5B, the semiconductor package 1A may include the solder ball terminals 550, the package substrate 500, the interposer solder balls 650, the interposer substrate 600, the semiconductor device 300, and a chip stack package 20A′. The solder ball terminals 550, the package substrate 500, the interposer solder balls 650, the interposer substrate 600, and the semiconductor device 300 may be substantially similar to those described above with reference to one or more example embodiments according to FIG. 4.

Further, the semiconductor package 20A described above with reference to one or more example embodiments according to FIG. 5A may be used as the chip stack package 20A′. The semiconductor package 1A may include the lower semiconductor chip 200, lower bonding bumps 250′, the first semiconductor chip 100A, the first bonding bumps 150A, the second semiconductor chip 100B, the second bonding bumps 150B, the third semiconductor chip 100C, and the third bonding bumps 150C. The lower semiconductor chip 200, first semiconductor chip 100A, first bonding bumps 150A, second semiconductor chip 100B, second bonding bumps 150B, third semiconductor chip 100C, and third bonding bumps 150C may be similar to those described above with reference to one or more example embodiments according to FIG. 5A. The lower bonding bumps 250′ may be provided on the lower surface of the lower semiconductor chip 200.

The lower bonding bumps 250′ may be provided between the upper interposer pads 620 and the fourth lower pads 271 and may be connected to the upper interposer pads 620 and the fourth lower pads 271. Each of the lower bonding bumps 250′ may include the lower conductive pattern 251 and a lower bonding structure 255. Formation of the lower bonding structure 255 may be performed by the method described above with reference to one or more example embodiments of FIGS. 2C and 2D. The lower bonding structure 255 may be provided between the lower conductive pattern 251 and the corresponding upper interposer pad 620. The lower bonding structure 255 may directly contact the corresponding upper interposer pad 620 and lower conductive pattern 251. The lower bonding structure 255 may include an intermetallic compound of a second metal and a solder material. According to one or more example embodiments, the lower bonding structure 255 may include an intermetallic compound of at least two metals selected from copper (Cu), tin (Sn), and silver (Ag). The intermetallic compound may further include a third metal. The third metal may include gold (Au). However, the content ratio of gold (Au) in the intermetallic compound may be less than the content ratio of copper, the content ratio of silver (Ag), and the content ratio of tin (Sn). The intermetallic compound may further include nickel. The content ratio of nickel in the second bonding structure 155B may be less than the content ratio of copper, the content ratio of tin, and the content ratio of silver (Ag) in the second bonding structure 155B. According to one or more example embodiments, the intermetallic compound may include an intermetallic compound of the second metal, the third metal, and the solder material.

According to one or more example embodiments, a thickness of the lower bonding structure 255 may be about 47% to about 54% of the sum of the thickness of the lower conductive pattern 251, the thickness of the lower bonding structure 255, and the thickness of the upper interposer pads 620. The sum of the thickness of the lower conductive pattern 251, the thickness of the lower bonding structure 255, and the thickness of the upper interposer pads 620 may be equal to a gap between the interposer substrate 600 and the lower semiconductor chip 200. Because the thickness of the lower bonding structure 255 satisfies the above conditions, the long-term reliability of the semiconductor package 1A may be improved.

The thickness of the lower conductive pattern 251 may be about 24% to about 28% of the sum of the thickness of the lower conductive pattern 251, the thickness of the lower bonding structure 255, and the thickness of the upper interposer pads 620. The thickness of the upper interposer pads 620 may be about 24% to about 28% of the sum of the thickness of the lower conductive pattern 251, the thickness of the lower bonding structure 255, and the thickness of the upper interposer pads 620. Because the thickness of the lower conductive pattern 251 and the thickness of the upper interposer pads 620 satisfy the above conditions, the long-term reliability of the semiconductor package 1A may be further improved.

While one or more example embodiments have has been particularly shown and described above, it will be apparent to those skilled in the art that various changes in form and details may be made therein without departing from the spirit and scope of the following claims.

What is claimed is:

1. A semiconductor package comprising:
a first semiconductor chip comprising a first through-via and a first upper pad;
a second semiconductor chip provided on the first semiconductor chip and comprising a second lower pad; and
a bonding bump provided between the first semiconductor chip and the second semiconductor chip and connected to the first upper pad and the second lower pad,
wherein the bonding bump comprises:
a conductive pattern directly contacting the second lower pad and comprising nickel; and
a bonding structure directly contacting the conductive pattern and the first upper pad,
wherein the bonding structure comprises an intermetallic compound comprising copper and a solder material, and
wherein a thickness of the bonding structure is from about 47% to about 54% of a sum of a thickness of the conductive pattern, a thickness of the bonding structure, and a thickness of the first upper pad.

2. The semiconductor package of claim 1, wherein the thickness of the conductive pattern is from about 24% to about 28% of the sum of the thickness of the conductive pattern, the thickness of the bonding structure, and the thickness of the first upper pad, and
wherein the thickness of the first upper pad is from about 24% to about 28% of the sum of the thickness of the conductive pattern, the thickness of the bonding structure, and the thickness of the first upper pad.

3. The semiconductor package of claim 1, wherein a void is provided within the bonding structure.

4. The semiconductor package of claim 1, wherein the first upper pad comprises nickel.

5. The semiconductor package of claim 1, wherein the solder material comprises at least one of tin (Sn) and silver (Ag),
wherein the intermetallic compound further comprises gold (Au), and
wherein a content ratio of gold (Au) in the intermetallic compound is less than a content ratio of copper, a content ratio of tin (Sn), and a content ratio of silver (Ag).

6. The semiconductor package of claim 1, wherein the solder material comprises at least one of tin (Sn) and silver (Ag),
wherein the intermetallic compound further comprises nickel, and
wherein a content ratio of nickel in the intermetallic compound is less than a content ratio of copper and a content ratio of the solder material.

7. The semiconductor package of claim 1, further comprising:
an insulating film provided between the first semiconductor chip and the second semiconductor chip,
wherein the insulating film covers a sidewall of the conductive pattern, a sidewall of the bonding structure, and a sidewall of the first upper pad, and
wherein the insulating film is spaced apart from the second lower pad.

8. The semiconductor package of claim 1, further comprising:
a third semiconductor chip disposed on an upper surface of the second semiconductor chip; and
an upper bonding bump provided between the second semiconductor chip and the third semiconductor chip,
wherein the second semiconductor chip further comprises a second through-via and a second upper pad,
wherein the third semiconductor chip comprises a third lower pad on a lower surface of the third semiconductor chip,
wherein the upper bonding bump comprises:
an upper conductive pattern directly contacting the third lower pad and comprising nickel; and
an upper bonding structure contacting the upper conductive pattern and the second upper pad,
wherein the upper bonding structure comprises an intermetallic compound comprising copper and a solder material, and
wherein a thickness of the upper bonding structure is from about 47% to about 54% of a sum of a thickness of the upper conductive pattern, a thickness of the upper bonding structure, and a thickness of the second upper pad.

9. The semiconductor package of claim 1, wherein the thickness of the bonding structure is from about 47% to about 54% of a gap between the first semiconductor chip and the second semiconductor chip.

10. The semiconductor package of claim 1, wherein a gap between the first semiconductor chip and the second semiconductor chip is from about 3 μm to about 7 μm.

11. A semiconductor package comprising:
a semiconductor chip comprising:
a lower pad;
a through-electrode; and
an upper pad,
wherein the upper pad is disposed on an upper surface of the semiconductor chip and is connected to the through-electrode; and
a bump provided on a lower surface of the semiconductor chip,
wherein the bump comprises:
a conductive pattern directly contacting a lower surface of the lower pad and comprising nickel;
a solder ball provided on a lower surface of the conductive pattern; and
a metal pattern directly contacting the lower surface of the conductive pattern and an upper surface of the solder ball and comprising copper,
wherein a maximum thickness of the solder ball is from about 50% to about 61% of a sum of a thickness of the conductive pattern, a thickness of the metal pattern, a maximum thickness of the solder ball, and a thickness of the upper pad, and
wherein the thickness of the metal pattern is from about 7% to about 9% of the sum of the thickness of the conductive pattern, the thickness of the metal pattern, the maximum thickness of the solder ball, and the thickness of the upper pad.

12. The semiconductor package of claim 11, wherein the thickness of the conductive pattern is from about 20% to about 25% of the sum of the thickness of the conductive pattern, the thickness of the metal pattern, the maximum thickness of the solder ball, and the thickness of the upper pad, and
wherein the thickness of the upper pad is from about 19% to about 24% of the sum of the thickness of the conductive pattern, the thickness of the metal pattern, the maximum thickness of the solder ball, and the thickness of the upper pad.

13. The semiconductor package of claim 11, further comprising:
an upper semiconductor chip disposed on the upper surface of the semiconductor chip and comprising a second lower pad;
an upper bonding bump provided between the semiconductor chip and the upper semiconductor chip and connected to the second lower pad; and
an insulating film provided between the semiconductor chip and the upper semiconductor chip and covering a sidewall of the upper bonding bump,
wherein the upper bonding bump comprises:
an upper conductive pattern contacting the second lower pad and comprising nickel; and
an upper bonding structure contacting the upper conductive pattern and the upper pad,
wherein the upper bonding structure comprises an intermetallic compound comprising copper and a solder material, and
wherein a thickness of the upper bonding structure is from about 47% to about 54% of a thickness of the insulating film.

14. The semiconductor package of claim 11, wherein the lower pad comprises aluminum, and
wherein the conductive pattern is directly contacting the lower surface of the lower pad.

15. A semiconductor package comprising:
a lower semiconductor chip comprising a conductive pad on an upper surface of the lower semiconductor chip;
lower bumps provided on a lower surface of the lower semiconductor chip;
a first semiconductor chip disposed on the upper surface of the lower semiconductor chip and comprising a first lower pad, a first through-via, and a first upper pad;
a first bonding bump provided between the lower semiconductor chip and the first semiconductor chip and connected to the conductive pad and the first lower pad;
a first insulating film provided between the lower semiconductor chip and the first semiconductor chip and covering a sidewall of the first bonding bump;
a second semiconductor chip disposed on an upper surface of the first semiconductor chip and comprising a second lower pad;
a second bonding bump provided between the first semiconductor chip and the second semiconductor chip and connected to the first upper pad and the second lower pad;
a second insulating film provided between the first semiconductor chip and the second semiconductor chip and covering a sidewall of the first bonding bump; and
a molding film disposed on the upper surface of the lower semiconductor chip and covering a sidewall of the first semiconductor chip and a sidewall of the second semiconductor chip,
wherein the first bonding bump comprises:
a first conductive pattern directly contacting the lower surface of the first lower pad and comprising nickel; and
a first bonding structure directly contacting the first conductive pattern and the conductive pad,
wherein the first bonding structure comprises a first intermetallic compound comprising copper and a solder material,
wherein the second bonding bump comprises:
a second conductive pattern contacting a lower surface of the second lower pad and comprising nickel; and
a second bonding structure directly contacting the second conductive pattern and the first upper pad,
wherein the second bonding structure comprises a second intermetallic compound comprising copper and a solder material,
wherein a thickness of the first bonding structure is from about 47% to about 54% of a gap between the lower semiconductor chip and the first semiconductor chip, and
wherein a thickness of the second bonding structure is from about 47% to about 54% of a gap between the first semiconductor chip and the second semiconductor chip.

16. The semiconductor package of claim 15, wherein a thickness of the first conductive pattern is from about 24% to about 28% of the gap between the lower semiconductor chip and the first semiconductor chip, and
wherein a thickness of the conductive pad is from about 24% to about 28% of the gap between the lower semiconductor chip and the first semiconductor chip.

17. The semiconductor package of claim 15, wherein a thickness of the second conductive pattern is from about 24% to about 28% of the gap between the first semiconductor chip and the second semiconductor chip, and
wherein a thickness of the first upper pad is from about 24% to about 28% of the gap between the first semiconductor chip and the second semiconductor chip.

18. The semiconductor package of claim 11, wherein a void is provided in the first bonding structure, and
wherein a second void is provided in the second bonding structure.

19. The semiconductor package of claim 15, further comprising:
a third semiconductor chip disposed on an upper surface of the second semiconductor chip and comprising a third lower pad;
a third bonding bump provided between the second semiconductor chip and the third semiconductor chip and connected to the third lower pad; and
a third insulating film provided between the second semiconductor chip and the third semiconductor chip and covering a sidewall of the third bonding bump,
wherein the second semiconductor chip further comprises a second through-electrode and a second upper pad,
wherein the third bonding bump comprises:
a third conductive pattern contacting a lower surface of the third lower pad and comprising nickel; and
a third bonding structure contacting the third conductive pattern and the second upper pad,
wherein the third bonding structure comprises a third intermetallic compound comprising copper and a solder material, and
wherein a thickness of the third bonding structure is from about 47% to about 54% of a gap between the second semiconductor chip and the third semiconductor chip.

20. The semiconductor package of claim 15, further comprising:
an interposer substrate comprising upper interposer pads; and
a semiconductor device disposed on an upper surface of the interposer substrate,
wherein the lower semiconductor chip is provided on the upper surface of the interposer substrate and is laterally apart from the semiconductor device, and
wherein the lower bumps are connected to the upper interposer pads.
